(19) United States
(12) Patent Application Publication
(10) Pub. No.: US 2025/0216460 A1
(43) Pub. Date: Jul. 3, 2025

(54) SENSOR SYSTEM FOR AN ELECTRIC MACHINE

(71) Applicant: Siemens Aktiengesellschaft, 80333 München (DE)

(72) Inventors: TOBIAS KATZENBERGER, Bad Königshofen STT Unteressfeld (DE); BASTIAN PLOCHMANN, Neustadt an der Aisch (DE)

(73) Assignee: Siemens Aktiengesellschaft, 80333 München (DE)

(21) Appl. No.: 18/853,317

(22) PCT Filed: Apr. 14, 2023
(86) PCT No.: PCT/EP2023/059803

§ 371 Date: Oct. 1, 2024

(30) Foreign Application Priority Data
Apr. 27, 2022 (EP) 22170171.7

(51) Int. Cl. G01R 31/34; G01R 31/12

(52) U.S. Cl. CPC G01R 31/343; G01R 31/1209

(57) ABSTRACT

A sensor system for an electric machine includes a sensor/transmitter apparatus arranged in a power connection area of the electric machine. The sensor/transmitter apparatus detects a physical measurement variable associated with the electric machine and to transmit a signal associated with the measurement variable when the measurement variable exceeds a previously defined threshold value. The physical measurement variable is voltage and the sensor/transmitter apparatus is designed to detect overvoltage in the electric machine. The sensor/transmitter apparatus includes a circuit which includes a resistor. The resistor includes a layer which is designed in such a way that a partial discharge in the layer during the overvoltage in the electric machine causes a value of the resistor to increase. A sensor/receiver apparatus is attached to an outside of the electric machine and designed to receive the signal from the sensor/transmitter apparatus and to provide notification that the threshold value has been exceeded.

The present disclosure relates to a sensor system for an electric, preferably rotatory machine comprising a sensor/transmitter apparatus and a preferably self-sufficient sensor/receiver apparatus, it being possible for the sensor/transmitter apparatus and the sensor/receiver apparatus to be attached externally on the machine, the sensor/transmitter apparatus being designed to detect at least one physical measurement variable associated with the machine and, if the measurement variable exceeds a previously defined threshold value, to transmit at least one signal associated with the measurement variable, the sensor/receiver apparatus being designed to receive the signal and to provide notification that the threshold value has been exceeded.

Furthermore, the present disclosure relates to an electric machine with such a sensor system.

In the low voltage industrial motor sector, the insulation system is designed to be partial discharge-free and cost-efficient by definition. However, the increasing use of inverters to control these motors means that, due to the steep switching edges of the inverters and the undefined long cable lengths in the power grid, overvoltage pulses can be present in the grid, which in the above-mentioned cost-effectively designed insulation system (favorable materials, favorable processes, defects not excluded) may result in partial discharges. These partial discharges cause a rapid degradation of the insulation system and thus a significantly reduced service life when electrical breakdown inevitably occurs.

In principle, systems for detecting partial discharges as such are known (see, for example, EP 3 715 883 A1, DE 600 25 927 T2, EP 2 857 852 A1).

The failure of the machine can currently only be predicted by active measurements and examinations of the insulation system by a technician in situ, which is not economical and customary in this price segment. In situ measurement and online feedback is not economical, especially in the price segment of these smaller motors as the common measurement and testing systems and the interfaces to a cloud service would significantly and unrealistically increase the manufacturing costs and thus the market price of the motors. A motor manufacturer and supplier cannot foresee the stress that the user will experience and therefore currently has no way of predicting the service life of the machine and a possible failure (“predictive maintenance”). Likewise, the user cannot be proven to have overstressed the machine and thus handled it incorrectly, which may result in replacement costs under the guarantee/warranty and may also damage the image if the products supplied fail prematurely within a short period of time.

It is therefore desirable for the status of the drive components of the motors to be permanently recorded and communicated. Motors and inverters can be equipped with corresponding connectivity modules for this purpose (see, for example, U.S. Pat. No. 6,297,742 B1, DE 10 2019 104 741 A1, US 2011/316691 A1). In this environment, modules are known that can detect all relevant operating and status data of a drive component via sensors, as well as a temperature meter, and transmit this data to an open IoT operating system.

Such modules are deliberately designed to be cost-effective, without a direct connection to the motor and can also be applied to existing motors (glued onto the housing, without a cable connection). The sensors are operated by means of a battery cell. This solution offers the first possibility to record physical parameters of the motor (mechanical/acoustic changes in the bearings, temperature increases on the housing) in situ and to mirror them online for predictive maintenance purposes.

The weak point here is that the parameters are recorded externally, i.e. only secondary effects, such as an increase in the housing temperature or acoustic changes in the bearings due to degradation of the lubricants caused by bearing currents, can be detected. Primary measurement variables, such as winding temperature, PD activity (PD für partial discharges) or electrical/capacitive changes in the motor circuit cannot be recorded due to the lack of physical coupling for cost reasons.

The object of the present invention is to provide a cost-effective sensor system which eliminates the aforementioned disadvantages and enables reliable detection of the overvoltage on the electric machine.

The object is achieved with a sensor system mentioned at the outset in that the sensor/transmitter apparatus is designed to be arranged in a power connection area of the electric machine, and the sensor/receiver apparatus is designed to be attached to the outside of the machine, the at least one physical measurement being variable voltage, and the sensor/transmitter apparatus being designed to detect overvoltage in the electric machine, the sensor/transmitter apparatus comprising a circuit, the circuit comprising a resistor, the resistor comprising a layer designed such that partial discharges occur in the layer during the overvoltage in the electric machine, whereby the value of the resistor increases.

In other words, the sensor/transmitter apparatus emits the signal when the value of the resistor exceeds a predetermined threshold value.

The sensor/transmitter apparatus is preferably designed to detect or measure the physical measurement variable associated with the machine immediately or directly. In this respect, the sensor/transmitter apparatus directly measures internal measurement variables of the machine or records the primary effects. In other words, the sensor/transmitter apparatus can be connected to the machine in such a way that a direct physical connection can be established between the sensor/transmitter apparatus and the machine and that through this direct/immediate physical connection, the physical variable can be detected (e.g. connection to voltage in order to detect voltage, to a temperature sensor in order to detect temperature, etc.).

The sensor/receiver apparatus can be self-sufficient insofar as it is not wired and therefore does not require an external power connection (operated by a battery, for example) to record measurement variables without a direct physical connection.

In one embodiment, it may be provided that the sensor/receiver apparatus is designed and/or configured to detect acoustic signals which are attributable, for example, to mechanical vibrations of a rotor of the machine and to determine the condition of the bearing depending, for example, on a frequency and/or the pattern of these acoustic signals. This enables the sensor/receiver apparatus to detect, for example, acoustic changes in the bearings due to degradation of the lubricants caused by bearing currents. The sensor/receiver apparatus thus detects secondary effects. In general, the sensor/receiver apparatus can be designed and/or configured to detect mechanical vibrations, e.g. vibrations, etc. from the machine and to interpret them (e.g. by frequency).

The signal emitted by the sensor/transmitter apparatus is event-triggered. The signal is associated with the recorded measurement variable in that it is only emitted if the aforementioned threshold value is exceeded.

The sensor/receiver apparatus is designed to receive the signal and is configured to evaluate the signal. For example, the sensor/receiver apparatus may include software that separates the signal, i.e. distinguishes it from others received, and assigns it to the physical variable associated with the signal.

In one embodiment, it may be provided that the signal has a predeterminable, preferably constant frequency. I.e., sensor/transmitter apparatus may be set to emit the signal of a predetermined frequency and/or a predetermined/defined pattern, e.g. pulsed (low frequency, possibly vibration, natural frequency from the housing of the machine).

It may be useful if the frequency of the signal lies outside the frequencies generated by the machine itself during operation. These are, in particular, acoustic frequencies which can be generated by various vibrations of the machine.

In one embodiment, it may be provided that the signal can have a predetermined, for example constant amplitude.

In one embodiment, it may be provided that the signal is a signal in the form of sound waves, for example ultrasound or an acoustic signal.

In one embodiment, it may be provided that the sensor/transmitter apparatus is structurally separate from the sensor/receiver apparatus.

In one embodiment, it may be provided that the sensor/receiver apparatus is set up to communicate via radio with at least one cloud service and to report the exceeding of the threshold value to the cloud service.

In one embodiment, it may be provided that the circuit of the sensor/transmitter apparatus is an electric or electronic circuit.

In one embodiment, it may be provided that the circuit comprises a resistor whose value depends on the value of the physical measurement variable associated with the machine.

In one embodiment, it may be provided that the circuit comprises a signal transmitter designed as an electronic component.

In one embodiment, it may be provided that the signal transmitter is designed as a piezo buzzer. The piezo buzzer can be active or passive, for example.

In one embodiment, it may be provided that the circuit comprises a transistor, in particular a field effect transistor-FET, for example a metal-oxide semiconductor field effect transistor-MOSFET.

The sensor/transmitter apparatus may comprise a power source. The power source is used to supply power to the signal transmitter so that it can emit the signal.

In one embodiment, it may be provided that the signal transmitter is operated via energy harvesting technologies such as thermoelectrics or vibration, or via power tapping in the power connection area, in particular in the terminal box.

In one embodiment, it may be provided that the power source is a battery, for example a button battery.

In one embodiment, it may be provided that the physical measurement variable is temperature, vibrations in a bearing of the machine, or current.

In one embodiment, it may be provided that if the physical measurement variable is a voltage, the resistor comprises a layer which is designed such that partial discharges occur in the layer during overvoltage, as a result of which a resistance value of the layer is increased.

The object is further achieved with an electric, for example rotatory machine, in particular with a low voltage motor, in that the machine comprises a housing, a power connection area accessible from the outside of the machine (for connecting the machine to power) and an aforementioned sensor system, the sensor/receiver apparatus, which is, for example, self-sufficient, being attached (for example fastened, in particular glued or clamped) to the outside of the housing of the machine, the sensor/transmitter apparatus being arranged in the power connection area (for example fastened).

Further features, properties and advantages of the present invention will emerge from the description which follows with reference to the accompanying figures. It is diagrammatically shown in:

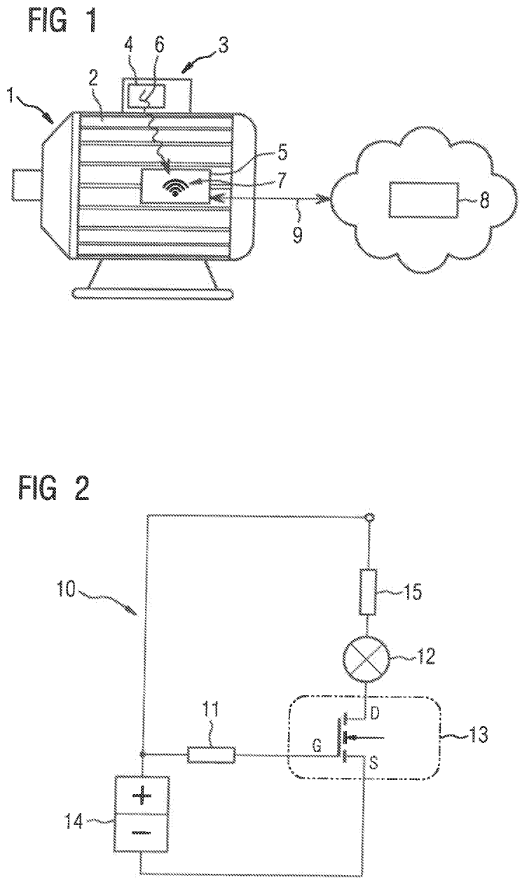

FIG. 1 a low voltage motor with a sensor system,

FIG. 2 a sensor/transmitter apparatus,

FIG. 1 shows a low voltage motor 1. The low voltage motor 1 has a housing 2. A power connection area 3 can be seen on the housing 2. The power connection area 3 is accessible from the outside of the low voltage motor 1 and is used to connect the low voltage motor 1 to power, for example to a supply network, e.g. via a supply unit (an inverter, in particular a frequency inverter).

In the present case, the power connection area 3 is designed in the form of a terminal box. The power connection area 3 is therefore that area of the low voltage motor 1 through which winding connections are accessible, for example by means of a terminal board. A sensor/transmitter apparatus 4 is arranged in the power connection area 3—here in the terminal box. Spaced apart from the sensor/transmitter apparatus 4, a sensor/receiver apparatus 5, which is self-sufficient for example, is attached to the outside of the housing 2 of the low voltage motor 1.

The sensor/transmitter apparatus 4 is designed to directly detect at least one physical measurement variable associated with the low voltage motor 1. This measurement variable can be, for example, the voltage or the temperature. If the measurement variable exceeds a predetermined threshold value, the sensor/transmitter apparatus 4 emits at least one signal 6. The signal 6 is thus event-triggered and in this respect associated with the detected measurement variable in that it is only emitted when the aforementioned threshold value is exceeded. The sensor/transmitter apparatus 4 can be set in such a way that it emits the signal 6 of a specific frequency and/or of a specific pattern which differ/differs from typical signal frequencies and/or patterns of the low voltage motor 1. The signal 6 can also have a predetermined, for example constant amplitude.

The sensor/transmitter apparatus 4 is structurally separate from the sensor/receiver apparatus 5, which is, for example self-sufficient. The sensor/receiver apparatus 5 can be self-sufficient insofar as it records external or secondary measurement variables of the low voltage motor 1 without a direct physical connection and can transmit these via radio 7. In particular, the sensor/receiver apparatus 5 is not connected to any other apparatus by cable. The sensor/receiver apparatus 5 is usually powered by a battery located in the sensor/receiver apparatus 5. This type of sensor/receiver apparatus is generally known in the prior art. They are often referred to as “SmartBox”.

In the present case, the sensor/transmitter apparatus 4 is developed in such a way that it can receive the signal 6 and report the exceeding of the threshold value for the physical variable associated with the signal.

For example, the sensor/receiver apparatus 5 may be configured to communicate 9 with at least one cloud service 8 via radio 7, for example WLAN, and to report the exceeding of the threshold value to the cloud service 8.

The signal 6 can be, for example, an acoustic signal. The signal 6 can also be another signal in the form of sound waves, e.g. an ultrasound signal.

It may be provided that the sensor/transmitter apparatus 4 comprises a circuit, for example an electric or electronic circuit 10.

Referring to FIG. 2, which illustrates an example of the circuit 10, it can be recognized that the circuit 10 may comprise a resistor 11. The resistor 11 does not have a fixed resistor value. The value of the resistor 11 changes depending on the value of the physical measurement variable associated with the low voltage motor 1. An immediate change in the resistor value of the resistor 11 depending on the physical variable means that the sensor/transmitter apparatus 4 is directly connected to the low voltage motor and measures the physical variable directly or measures the primary effect of this variable.

If the physical measurement variable is a voltage, it may be useful if the resistor 11 comprises a layer (not shown here) which is designed in such a way that partial discharges occur in the layer in the event of overvoltage in the low voltage motor 1, whereby the resistor value of the layer is increased.

Such a layer is known, for example, from the application EP 3 505 943 A1 of the applicant. This layer can be arranged, for example, in the terminal box 3 of the low voltage motor 1 and is suitable for detecting an electric overvoltage between two electrical conductors, for example windings in the terminal box 3. The layer comprises, for example, a conductor track carrier made of an electrically insulating carrier material and at least two conductor tracks spaced apart from each other on the conductor track carrier. In order to detect the overvoltage between two electrical conductors, each electrical conductor is to be electrically connected to at least one of the conductor tracks, with no conductor track being electrically connected to both electrical conductors, and the conductor tracks are designed and arranged in such a way that a (predetermined) overvoltage between the electrical conductors causes a partial discharge between the first conductor track and a conductor track which is electrically connected to one of the two electrical conductors, said partial discharge changing the electrical resistor of the first conductor track. If the electrical resistor value of the first conductor track exceeds a predetermined threshold value, a signal 6 is triggered.

The first conductor track can therefore be used as a resistor 11.

Further details about the layer can be found in the application EP 3 505 943 A1, paragraphs to [0048], FIG. 1-4 and in particular paragraphs to [0035], FIGS. 1 and 2.

With such a resistor 11, overvoltage and voltage pulses can be detected in the terminal box 3. I.e. no measurement of each individual overvoltage is shown, but an overvoltage activity integrated over time is detected.

The layer can, for example, be designed as a composite paint layer. The layer is inexpensive. For example, it can be inserted between the phases and earth in the terminal box 3.

Due to a suitable geometric structure of this layer and defined conductor tracks, targeted partial discharges occur in the layer in the event of overvoltage, which increasingly change it intrinsically. Through irreversible oxidation of the ceramic filler particles (depletion edge layers of the tin oxide particles as fillers in the plastic matrix), the resistor 11 can irreversibly increase by several orders of magnitude and thus be used as a measurement variable for the electrical stress over time.

In order to generate signals 6, the sensor/transmitter apparatus 4 can have a signal transmitter 12.

In FIG. 2, the signal transmitter 12 is shown as part of the circuit 10. The signal transmitter 12 can, for example, be designed as a piezo buzzer.

Furthermore, it can be seen from FIG. 2 that the circuit 10 can comprise a transistor in the form of a metal-oxide semiconductor field effect transistor 13—MOSFET for short—with the connections: Gate G, Source S and Drain D. For example, the resistor 11 can be connected via the gate terminal G, preferably directly to the gate terminal G, and thus control the opening between the source terminal S and the gate terminal G. Depending on the circuit of the MOSFET 13, this can be done in both directions—i.e. continuity if high impedance or low impedance.

For example, the signal transmitter 12 can be connected directly to the drain connection D.

The sensor/transmitter apparatus 4 can include a power source. The power source is used to supply the signal transmitter 12 with power so that it can transmit the signal 6.

FIG. 2 shows that the power source can be designed as a battery 14 and can be connected to the signal transmitter 12 via the MOSFET 13 (via source/drain connection S/D).

Another example of the physical measurement variable is the temperature. For example, the low voltage motor 1 can have a temperature sensor which, for example, ends in the terminal box 3. The temperature sensor can, for example, be designed as a resistance temperature detector (RTD), e.g. of the PT 100 or PT 1000 type. This allows the respective temperatures in the motor to be measured.

The resistor 11 can therefore be designed as a temperature sensor. As a result, excess temperatures in the motor 1, for example in the slot and in the winding head of the motor 1, can be reported in situ via the signal 6.

In addition, this simplifies temperature measurement. Until now, the measured value analysis has been carried out by a service technician and the active connection and reading of the values during operation. This is much more time-consuming compared to the proposed method, in which the exceeding of a specified temperature threshold value is reported by emitting the signal 6.

In addition, it is conceivable to detect other condition-relevant measurement variables, such as vibrations in a bearing of the low voltage motor 1, which indicate the quality of the lubricants and thus the reduced service life of the bearing. An electric evaluation of the currents is also possible in order to determine whether the low voltage motor 1 is being operated at the ideal nominal point and thus in the range of maximum efficiency. User assistance (e.g. by means of repeated notification) or a direct, intelligent optimization could thus increase consumption and thus resource efficiency, as well as extending the service life of the motor 1.

The resistor 15 schematically designates a resistor of the wiring of the circuit 10 and/or the inner resistor of the signal transmitter 12.

In summary, the present disclosure shows a possibility of coupling measurement variables, for example temperature, PD (partial discharges) activity described above, to the SmartBox via, for example, an acoustic signal transmitter. Here, a commercially available piezo buzzer (unit price in the cent range) can be used and can be permanently operated by means of a battery button cell (or possibly via energy harvesting technologies such as thermoelectrics or vibration, or via power tapping in the terminal board).

Due to the acoustic connection to the SmartBox, for example, a particularly cost-effective measurement and transmission of the measurement variable is possible.

The transmission of status signals to an existing coupling electronics assembly (SmartBox) is possible via various physical mechanisms. Ideally, a mechanism is used which is already present as a detector in the coupling electronics, such as sound. Different frequencies and patterns can be used (low frequency, possibly vibration, natural frequency of the housing) up to ultrasound.

The object of this description is merely to provide illustrative examples and to specify further advantages and special features of this invention. Thus, it cannot be interpreted as limiting the scope of the invention or the patent rights claimed in the claims.

What is claimed is:

1.-16. (canceled)

17. A sensor system for an electric machine, the sensor system comprising:
a sensor/transmitter apparatus arranged in a power connection area of the electric machine, said sensor/transmitter apparatus designed to detect a physical measurement variable associated with the electric machine and to transmit a signal associated with the measurement variable when the measurement variable exceeds a previously defined threshold value, wherein the physical measurement variable is voltage and the sensor/transmitter apparatus is designed to detect overvoltage in the electric machine, said sensor/transmitter apparatus comprising a circuit which comprises a resistor, said resistor comprising a layer which is designed in such a way that a partial discharge in the layer during the overvoltage in the electric machine causes a value of the resistor to increase; and
a sensor/receiver apparatus designed for attachment to an outside of the electric machine, the sensor/receiver apparatus designed to receive the signal from the sensor/transmitter apparatus and to provide notification that the threshold value has been exceeded.

18. The system of claim 17, wherein the sensor/transmitter apparatus is structurally separate from the sensor/receiver apparatus.

19. The system of claim 17, wherein the sensor/receiver apparatus is designed to communicate via radio with a cloud service and to report to the cloud service when the threshold value has been exceeded.

20. The system of claim 17, wherein the signal is a signal in a form of sound waves.

21. The system of claim 17, wherein the signal is a signal in a form of ultrasound or an acoustic signal.

22. The system of claim 17, wherein the signal has a predeterminable frequency.

23. The system of claim 22, wherein the frequency is constant.

24. The system of claim 17, wherein the sensor/transmitter apparatus is designed as a circuit.

25. The system of claim 17, wherein the circuit comprises a signal transmitter designed as an electronic component.

26. The system of claim 25, wherein the signal transmitter is designed as a piezo buzzer.

27. The system of claim 25, wherein the signal transmitter is designed to be operated via energy harvesting technologies.

28. The system of claim 25, wherein the signal transmitter is designed to be operated via thermoelectrics or vibration, or via power tapping in the power connection area.

29. The system of claim 17, wherein the circuit comprises a transistor, in particular a field effect transistor.

30. The system of claim 29, wherein the field effect transistor is a metal-oxide semiconductor field effect transistor.

31. The system of claim 17, wherein the sensor/transmitter apparatus comprises a power source.

32. The system of claim 31, wherein the power source is designed as a battery, for example a button battery.

33. The system of claim 17, wherein the sensor/transmitter apparatus is designed to detect another physical measurement variable selected from the group consisting of temperature, vibration in a bearing of the electric machine, and current.

34. The system of claim 17, wherein the value of the resistor depends on a value of the physical measurement variable.

35. An electric machine, comprising:
a housing;
a power connection area accessible from outside of the electric machine; and
a sensor system comprising a sensor/transmitter apparatus arranged in the power connection area, said sensor/transmitter apparatus designed to detect a physical measurement variable associated with the electric machine and commensurate with voltage and to transmit a signal associated with the measurement variable when the measurement variable exceeds a previously defined threshold value, wherein the physical measurement variable is voltage and the sensor/transmitter apparatus is designed to detect overvoltage in the electric machine, said sensor/transmitter apparatus comprising a circuit which comprises a resistor, said resistor comprising a layer which is designed in such a way that a partial discharge in the layer during the overvoltage in the electric machine causes a value of the resistor to increase, the sensor system further comprising a sensor/receiver apparatus designed for attachment to an outside of the housing, the sensor/receiver apparatus designed to receive the signal from the sensor/transmitter apparatus and to provide notification that the threshold value has been exceeded.

36. The electric machine of claim 35, wherein the electric machine is designed as a low voltage motor.
